(19) United States
(12) Patent Application Publication
(10) Pub. No.: US 2026/0038767 A1
(43) Pub. Date: Feb. 5, 2026

(54) PULSE-MODE CONTROL IN A BIAS SUPPLY

(71) Applicant: Advanced Energy Industries, Inc., Denver, CO (US)

(72) Inventor: Faleh Alskran, Timnath, CO (US)

(21) Appl. No.: 18/794,876

(22) Filed: Aug. 5, 2024

(51) Int. Cl. H01J 37/32

(52) U.S. Cl. CPC H01J 37/32174; H01J 37/32128; H01J 37/32935

(57) ABSTRACT

Bias supplies and bias control methods are disclosed. One method comprises applying, during an ON pulse, a waveform using switching in connection with a DC voltage, removing the DC voltage while circulating current during an OFF pulse, reapplying the DC voltage, in advance of another ON pulse, and initiating the switching after reapplying the DC voltage to reapply the waveform during another ON pulse.

### BACKGROUND

### Field

The present invention relates generally to power supplies, and more specifically to power supplies for applying a voltage for plasma processing.

### Background

Many types of semiconductor devices are fabricated using plasma-based etching techniques. If it is a conductor that is etched, a negative voltage with respect to ground may be applied to the conductive substrate to create a substantially uniform negative voltage across the surface of the substrate conductor, which attracts positively charged ions toward the conductor, and as a consequence, the positive ions that impact the conductor have substantially the same energy.

If the substrate is a dielectric, however, a non-varying voltage is ineffective to place a voltage across the surface of the substrate. But an alternating current (AC) voltage (e.g., high frequency AC or time varying periodic voltage waveform may be applied by a bias supply to the conductive plate (or chuck) so that the AC field induces a voltage on the surface of the substrate. During a negative portion of the applied waveform, the surface of the substrate will be charged negatively, which causes ions to be attracted toward the negatively-charged surface during the negative portion of the periodic cycle. And when the ions impact the surface of the substrate, the impact dislodges material from the surface of the substrate—effectuating the etching.

During operation of a bias supply, the bias supply undergoes state changes such as from an off state to an on state. In addition, the periodic waveform may by changed, consistent with state changes, to effectuate different ion energy distribution functions (IEDFs). For example, on directionality, feature profile, and selectivity to a mask and a stop-layer may be controlled by making state changed to the bias supply to adjust the IEDF.

In recent years, advanced plasma processing systems have turned to using pulsed plasmas for several reasons. In one instance, pulsing is used to reduce the average energy imparted to a wafer. For example, to achieve a desired etch rate or depth of an etched feature, high powers, such as ten or more kilowatts of bias power, may be used. Unfortunately, continuous application of such high power might damage the wafer or process hardware, so pulsing of a source supply is used to reduce average power delivered by reducing the duty cycle. In another instance, pulsing is used to control the electron temperature in the plasma.

### SUMMARY

In some aspects, the techniques described herein relate to an apparatus to produce a waveform, the apparatus including: at least one switch in a current path that couples a first node to a second node; a power supply coupled to the current path; a controller configured to: while the power supply is applying power, repeatedly close and open the at least one switch to produce peak voltages and portions between the peak voltages; and while the power supply is not applying power, close the at least one switch to circulate current through the at least one switch and the power supply.

In some aspects, the techniques described herein relate to an apparatus, wherein the controller is configured to control the power supply to apply power in advance of an ON pulse.

In some aspects, the techniques described herein relate to an apparatus, wherein the controller is configured to receive a signal that indicates when the ON pulse begins.

In some aspects, the techniques described herein relate to an apparatus, wherein the second node is coupled to the first node via a first inductor to form the current path.

In some aspects, the techniques described herein relate to an apparatus, wherein the power supply is arranged in series with a second inductor, and the series arrangement of the power supply and the second inductor is coupled between the current path and the second node.

In some aspects, the techniques described herein relate to an apparatus, wherein the current is circulated through the at least one switch, the second inductor, and the power supply.

In some aspects, the techniques described herein relate to an apparatus, wherein the power supply is controllable to control current provided to the first node to control a ramped voltage between each of the peak voltages at the first node.

In some aspects, the techniques described herein relate to a method for producing a waveform including: applying, during an ON pulse, a waveform using switching in connection with a DC voltage; removing the DC voltage while circulating current during an OFF pulse; reapplying, in advance of another ON pulse, the DC voltage; and initiating the switching after reapplying the DC voltage to reapply the waveform during another ON pulse.

In some aspects, the techniques described herein relate to a method, wherein applying the waveform includes repeatedly coupling a voltage to, and decoupling the voltage from, a first node to produce peaks of the waveform.

In some aspects, the techniques described herein relate to a method, wherein applying the waveform includes repeatedly coupling the first node to, and decoupling the first node from, a second node via a switch and a first inductor to produce the peaks of the waveform.

In some aspects, the techniques described herein relate to a method including: providing the DC voltage to a second inductor to produce current to create a negative voltage ramp between each of the peaks of the waveform.

In some aspects, the techniques described herein relate to a method, wherein each cycle of the waveform includes a peak voltage, a voltage step following the peak voltage, and a ramped voltage following the voltage step.

In some aspects, the techniques described herein relate to a method, wherein the DC voltage is a greater magnitude than −1000 volts.

In some aspects, the techniques described herein relate to a system, the system including: a source generator configured to apply pulsed power to a plasma chamber; and a bias supply configured to: apply, during an ON pulse of the source generator, a waveform using switching in connection with a DC voltage; removing the DC voltage while circulating current during an OFF pulse of the source generator; reapply, in advance of another ON pulse, the DC voltage; and initiating the switching after reapplying the DC voltage to reapply the waveform during the other ON pulse.

In some aspects, the techniques described herein relate to a system, wherein the bias supply is configured to apply the waveform by repeatedly coupling a voltage to, and decoupling the voltage from, a first node to produce peaks of the waveform.

In some aspects, the techniques described herein relate to a system, wherein the bias supply is configured to apply the waveform by repeatedly coupling the first node to, and decoupling the first node from, a second node via a switch and a first inductor to produce the peaks of the waveform.

In some aspects, the techniques described herein relate to a system wherein the bias supply is configured to provide the DC voltage to a second inductor to produce current to create a negative voltage ramp between each of the peaks of the waveform.

In some aspects, the techniques described herein relate to a system, wherein each cycle of the waveform includes a peak voltage, a voltage step following the peak voltage, and a ramped voltage following the voltage step.

In some aspects, the techniques described herein relate to a system, wherein the DC voltage is a greater magnitude than −1000 volts.

### BRIEF DESCRIPTION OF THE DRAWINGS

FIG. 1 is a block diagram depicting an exemplary plasma processing environment;

FIG. 2 is a schematic diagram depicting an exemplary bias supply;

FIG. 3 is a schematic diagram electrically representing aspects of a plasma processing chamber;

FIG. 4 is a flowchart depicting a method;

FIG. 5 depicts graphs and a timing diagram depicting operational aspects of a bias supply;

FIG. 6 is a diagram depicting graphs representing examples of pulses of a source generator and operation of a bias supply; and

FIG. 7 is a diagram depicting components that may be utilized to implement control aspects disclosed herein.

### DETAILED DESCRIPTION

The word “exemplary” is used herein to mean “serving as an example, instance, or illustration.” Any embodiment described herein as “exemplary” is not necessarily to be construed as preferred or advantageous over other embodiments.

Preliminary note: the flowcharts and block diagrams in the following Figures illustrate the architecture, functionality, and operation of possible implementations of systems, methods and computer program products according to various embodiments. In this regard, some blocks in these flowcharts or block diagrams may represent a module, segment, or portion of code, which comprises one or more executable instructions for implementing the specified logical function(s). The instructions may be executable by a processor or may be used to program a field programmable gate array. It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

For the purposes of this disclosure, source generators, source supplies, or excitation supplies are those whose energy is primarily directed to generating and sustaining the plasma, while “bias supplies” are those whose energy is primarily directed to generating a surface potential for attracting ions and electrons from the plasma.

Applicant has found that when a bias supply undergoes state changes, the periodic voltage waveform and/or current waveform output by the bias supply may have undesirable rise and/or fall times. An aspect of the present disclosure is control, during a transition between one operational state of a bias supply to another operational state of the bias supply, to mitigate against slow rise and/or fall times. The state changes that the bias supply undergoes may or may not be in the context of a pulsed plasma, and the transition control may occur on an ongoing basis while applying state changes to effectuate a specific recipe that is applied to a workpiece (also referred to herein as a substrate).

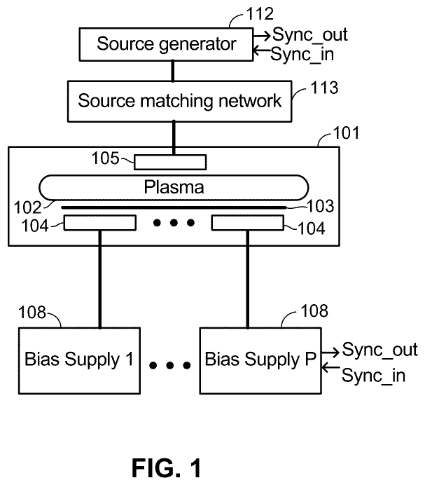

Referring first to FIG. 1, shown is an exemplary plasma processing environment (e.g., deposition or etch system) in which bias supplies may be utilized. The plasma processing environment may include many pieces of equipment coupled directly and indirectly to a plasma processing chamber 101, within which a volume containing a plasma 102 and workpiece 103 (e.g., a wafer) and electrodes 104 (which may be embedded in a substrate support) are contained. The equipment may include vacuum handling and gas delivery equipment (not shown), one or more bias supplies 108, one or more source generators 112, and one or more source matching networks 113. In many applications, power from a single source generator 112 is connected to one or multiple source electrodes 105. The source generator 112 may be a higher frequency RF generator (e.g., 13.56 MHz to 120 MHz). The electrode 105 generically represents what may be implemented with an inductively coupled plasma (ICP) source, a dual capacitively-coupled plasma source (CCP) having a secondary top electrode biased at another RF frequency, a helicon plasma source, a microwave plasma source, a magnetron, or some other independently operated source of plasma energy.

In variations of the system depicted in FIG. 1, the source generator 112 and source matching network 113 may be replaced by, or augmented with, a remote plasma source. And other variations of the system may include only a single bias supply 108. It should be recognized that many other variations of the plasma processing environment depicted in FIG. 1 may be utilized. As examples without limitation, U.S. Pat. No. 10,707,055, issued Jul. 7, 2020 and U.S. Pat. No. 10,811,227, issued Oct. 20, 2020, both of which are incorporated by reference in their entirety, disclose various types of system designs.

As shown in FIG. 1, each of the source generator 112 and the bias supply 108 may receive a synchronization signal, sync_in, and each of the source generator 112 and the bias supply 108 may provide a synchronization signal, sync_out. One of ordinary skill in the art will ready appreciate that the source generator 112 may operate as a main supply (providing the sync_out signal) while a bias supply 108 operates as a satellite supply (receiving the sync_in signal), or the bias supply 108 may operate as a main supply (providing the sync_out signal) while the source supply operates as a satellite supply (receiving the sync_in) signal.

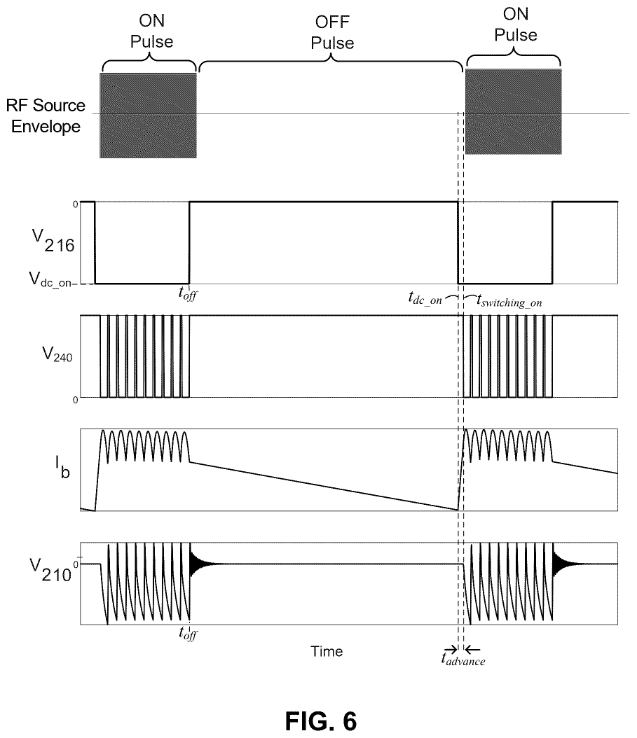

The synchronization between the source generator 112 and the bias supply 108 enables a pulse mode of operation in the depicted system. Referring briefly to FIG. 6 for example, shown is an RF source envelope that may be provided by the source generator 112. As shown, the RF source envelope may change from an ON pulse to an OFF pulse, and the bias supply 108 may output multiple cycles of a periodic voltage waveform, V₂₁₀, during each pulse ON pulse. Although not shown in FIG. 6, it is certainly contemplated that the magnitude of the output of the source generator 112 may change and the voltage levels of the periodic voltage waveform may change from pulse to pulse. In FIG. 6, the cycles of the periodic voltage waveform, V₂₁₀, are depicted while the cycles of the source generator are not depicted because (typically) the frequency of the periodic voltage waveform is hundreds of kilohertz (e.g., 400 kHz), and in contrast, the frequency of the source generator 112 may be in the megahertz (e.g., 13.56 MHz). As a consequence, the waveform of the source generator 112 is not shown in FIG. 6, and instead, envelopes are shown.

It should be recognized that, while the following disclosure generally refers to plasma-based wafer processing, implementations can include any substrate processing within a plasma chamber. In some instances, objects other than a substrate can be processed using the systems, methods, and apparatus herein disclosed. In other words, this disclosure applies to plasma processing of any object within a sub-atmospheric plasma processing chamber to affect a surface change, subsurface change, deposition or removal by physical or chemical means.

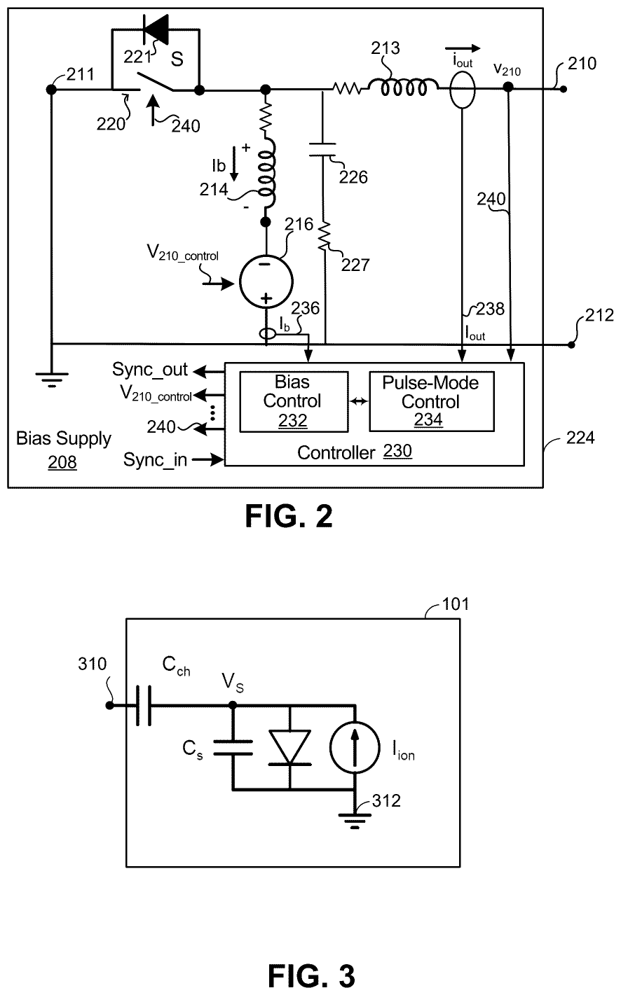

Referring to FIG. 2, shown is an exemplary bias supply 208 that may be utilized to implement the bias supplies 108 described with reference to FIG. 1. It should be recognized that the bias supply 208 depicts only an example of a topology that may be utilized and the bias supply 208 may be realized by variations of the depicted topology. As shown, the bias supply 208 includes a first node 210 (which may be an output node), second node 211, and a third node 212 (which may be a return node), a first inductor 213, a series combination of a second inductor 214 and a power supply 216, and a switch 220. As shown, a diode 221 is in parallel with the conduction path of the switch 220, and this diode 221 may be an intrinsic diode (e.g., when the switch 220 is realized by a MOSFET), or the diode 221 may be added as an external diode. As discussed further herein, the power supply may be a DC power supply that is capable of providing a range of DC voltages and is capable of being turned on and off responsive to a V₂₁₀ control signal. The DC voltages may be, for example and without limitation, negative voltages in the hundreds of volts or may be several thousand volts. As a specific example, a magnitude of the DC voltage may be greater than −1000 volts.

As shown, the switch 220 couples the second node 211 to the first node 210 via the first inductor 213 to form (when the switch 220 is closed) a current path between the second node 211 and the first node 210, and the series combination of the power supply 216 and the second inductor 214 are coupled between the third node 212 and the current path that comprises the switch 220 and the first inductor 213. Also shown is an optional snubber capacitor 226 that may be arranged in series with an optional resistor 227 to form a resistance-capacitance branch. It should be recognized that the resistor 227 is optional if the snubber capacitor 226 is utilized. As discussed further herein, the waveform at the first node may be produced by repeatedly coupling a voltage (e.g., a voltage at the second node 211) to, and decoupling the voltage from, the first node 210 to produce peaks of the waveform. More specifically, the first node 210 may be repeatedly coupled to, and decoupled from, the voltage at the second node 211 via the switch 220 and the first inductor 213 to produce the peaks of the waveform. And as discussed further herein, providing the DC voltage from the power supply 216 to the second inductor 214 produces current to create a negative voltage ramp between each of the peaks of the waveform.

In general, the bias supply 208 functions to apply an asymmetric periodic voltage function while also being capable of operating in a pulse mode. In the depicted embodiment, current delivered to a load through the first node 210 is returned to the bias supply 208 through the third node 212 that may be common with the load.

FIG. 2 also depicts examples of electrical parameters that are associated with the bias supply 208 including inductor current, Ib, that flows through the second inductor 214, which may be measured along a current path that includes the inductor 214 and the power supply 216. Yet another electrical parameter that may be measured is output current, Iout, which may be measured along the current path, as shown, between the switch 220 and the first node 210. In addition, the output voltage, V₂₁₀, is another electrical parameter that may be measured and utilized as described herein. V₂₁₀, for example, may be the voltage across the first node 210 and the third node 212. As described herein, the third node 212 may be grounded in some variations of the bias supply 208 or may be another non-zero voltage. It should be recognized that other electrical parameters of the bias supply 208 may be monitored and/or measured depending upon the particular design of the bias supply 208.

As shown, the bias supply 208 may include a controller 230 that functions to control the power supply 216 and the switch 220 based upon one or more settings and one or more of the electrical parameters (e.g., Ib, Iout, and V₂₁₀). The controller 230 may reside within a housing 224 of the bias supply 208, or alternatively, may reside external to the housing 224 of the bias supply 208. When implemented external to the housing 224 of the power supply 208, the controller 230 may be implemented as a portion of a centralized controller that controls several pieces of processing equipment such as, for example and without limitation, the bias supply 208, the source generator 112, the source matching network 113, other bias supplies 208, mass flow controllers, and other components. The controller 230 may also be distributed between the bias supply 208 and control-related components that are external to the bias supply 208. It is also contemplated that the controller 230 may be implemented within a housing of another piece of equipment such as the source generator 112 or the controller 230 may be implemented as a distributed controller that resides in several pieces of equipment.

As shown, the controller 230 comprises a bias control portion 232 and a pulse-mode control module 234. The depiction of the bias control portion 232 and the pulse-mode control module 234 is logical for purposes of describing functional aspects of the controller 230, but is should be recognized that the bias control portion 232 and the pulse-mode control module 234 may be realized by common hardware constructs. For example, the bias control portion 232 and the pulse-mode control module 234 may share one or more common processors and/or field programmable gate arrays (FPGAs). As one of ordinary skill in the art will appreciate, processor executable instructions and/or instructions to program an FPGA may be utilized to effectuate control methods described further herein.

The controller 230 may receive and may provide several signals. For example, without limitation, the controller 230 may receive a signal 236 indicative of Ib, a signal 238 indicative of Iout, a signal 240 indicative of V₂₁₀, and a sync_in signal. In addition, the controller 230 may provide several signals including and without limitation, a gate drive signal 240 to control the switching of the switch 220; a sync_out signal that may be used when the bias supply is operating as a main supply; and the V_{210_control} signal to control the magnitude of the voltage output by the power supply 216. As one of ordinary skill in the art will appreciate, these signals may be analog or may be digital signals.

In general, the bias control portion 232 is configured to control the switch 220 and the power supply 216 to effectuate desired aspects of the asymmetrical periodic voltage waveform (as described further herein) that is applied to the first node 210 and the third node 212. The pulse-mode control module 234 generally operates, as described further herein, in connection with the bias control portion 232 to modify operation of the bias control portion 232 during transitions between control states to result in increased rise and fall times of the periodic voltage waveform from one control state to another control state. The bias control portion 232 and the pulse-mode control module 234 may be realized by hardware in connection with software (e.g., as firmware). For example, algorithms for effectuating the functions of the pulse-mode control module 234 may be embodied in processor executable code that is executed by a processor. Prior art bias supplies are not capable of the pulse-mode control functionality, at least, because they have not been programmed to be configured as described herein. More detail about the operation of the bias supply 208 are provided further herein, but first it is helpful to understand aspects of a plasma load.

Referring briefly to FIG. 3, shown is a schematic drawing that electrically depicts aspects of an exemplary plasma load within the plasma processing chamber 101. As shown, the plasma processing chamber 101 may be represented by a chuck capacitance C_{ch} (that includes a capacitance of a chuck and workpiece 103) that is positioned between an input 310 (also referred to as an input node 310) to the plasma processing chamber 101 and a node representing a sheath voltage, V_{S}, at a surface of the workpiece 103 (also referred to as a wafer substrate 103). As a consequence, references to the sheath voltage, V_{S}, are also referred to herein as a voltage at a surface of the wafer or substrate. In addition, a return node 312 (which may be a connection to ground) is depicted. The plasma 102 in the processing chamber is represented by a parallel combination of a sheath capacitance C_{S}, a diode, and a current source. The diode represents the non-linear, diode-like nature of the plasma sheath that results in rectification of the applied AC field, such that a direct-current (DC) voltage drop, appears between the workpiece 103 and the plasma 102.

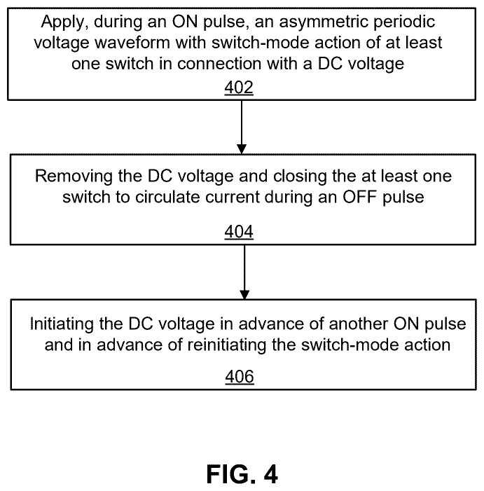

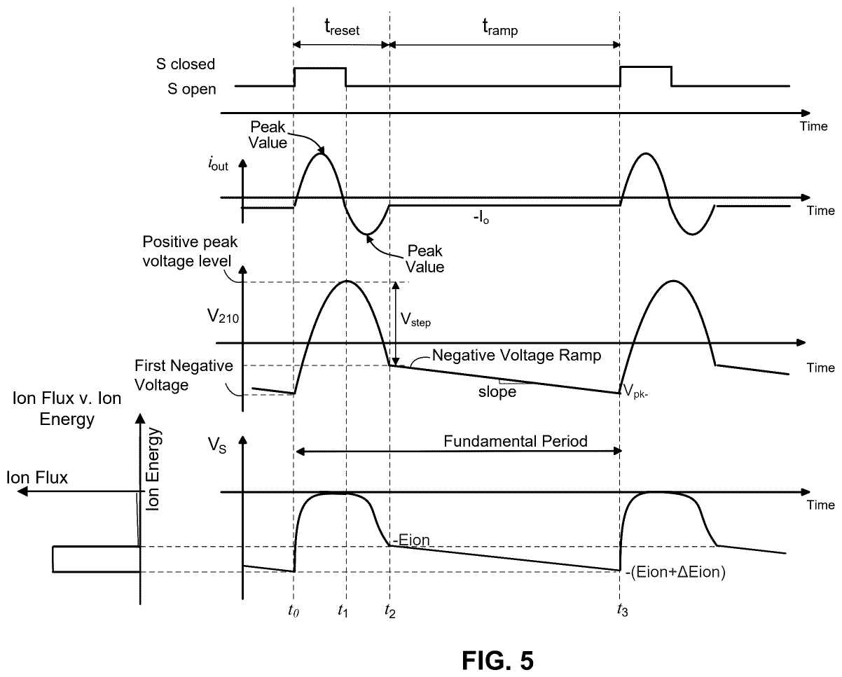

Referring back to FIG. 2, simultaneous reference is made to FIG. 4, which is a flowchart depicting a control method that may be traversed in connection with embodiments disclosed herein. In addition, reference is also made to FIG. 5 and FIG. 6. FIG. 5 depicts an example timing diagram for the switch 220 in connection with an asymmetric periodic waveform, V₂₁₀, at node 210, and FIG. 6 depicts several parameters for the source generator 112 and the bias supply 208. As shown, during an ON pulse (shown in FIG. 6), an asymmetric periodic voltage waveform, V₂₁₀, is applied with switch-mode action (of the switch 220) in connection with a DC voltage, V₂₁₆, from the power supply 216 (Block 402). More specifically, while the power supply 216 is applying the DC voltage V₂₁₆ (shown in FIG. 6), to produce a cycle of the asymmetric periodic waveform, as shown in FIG. 5, the switch 220 is closed and opened to produce a peak voltage at the first node 210 before a voltage at the first node drops by a voltage step, Vstep, followed by a negative voltage ramp. The DC voltage V₂₁₆ applied by the power supply 216 may be a negative voltage, Vdc_on, that may be for example, hundreds of negative volts or thousands of negative volts.

Referring again to FIG. 5, an asymmetric periodic voltage waveform, V₂₁₀, (from time t0 to t3) may comprise a first portion (from time t0 to t1) that begins with a first negative voltage and changes to a positive peak voltage (at time t1) during the first portion, the asymmetric periodic voltage also changes from the first portion to a third voltage level (at time t2) during a second portion (from time t1 to t2), and the asymmetric periodic voltage waveform comprises a third portion (from time t2 to t3) that includes a voltage ramp between the third voltage level and a fourth, negative voltage level (at time t3).

As shown in FIG. 5, the asymmetric periodic voltage waveform also comprises the voltage step, Vstep, between times t1 and t2, and Vstep corresponds to a sheath voltage at t2 that produces ions at any energy level, −Eion. And during the third portion of the asymmetric periodic voltage waveform, the sheath voltage may become more negative so that at t3, ions at an energy level of Eion+ΔEion are produced. Also shown in FIG. 5 is a negative voltage peak, Vpk−, which identifies an end to the third portion of the asymmetric periodic voltage function. The negative voltage peak, Vpk− may be used as a control parameter. For example, a threshold value for the negative voltage peak, Vpk− may trigger the closing of the switch 220.

A fundamental period (from t0 to t3) of the asymmetric periodic voltage waveform may be adjusted to adjust a spread of ion energies. As shown in FIG. 5, a full current cycle occurs between times t0 and t2 during the first and second portions of the asymmetric periodic voltage waveform. And the time between full current cycles is the time, tramp, between t2 and t3.

As shown, the switch 220 may be controlled so that output current, Iₒᵤₜ, completes a full cycle from −Iₒ to a peak value, back to −Iₒ, to a peak value in an opposite direction and back to −Iₒ. It should be recognized the peak value of the current in a first half of the current cycle may be different than the peak value of the current in the second half of the current cycle.

During an OFF pulse, the DC voltage, V₂₁₆, from the power supply 216 is removed while the switch 220 is closed to circulate current within the bias supply 208 (Block 404). For example, as shown in FIG. 6, the power supply 216 may be turned off at a time, t_{off}, to create a short circuit to ground so that the asymmetric periodic voltage waveform quickly falls to zero volts. In addition, as shown by the voltage of the gate drive signal, V₂₄₀, in FIG. 6, the switch 220 is closed at the time, t_{off}, to circulate current, Ib, through the switch 220, the second inductor 214, and the power supply 216. In some modes of operation, the OFF pulse is short enough so that the current, Ib, circulated through the switch 220, the second inductor 214, and the power supply 216 does not completely decay to zero amps; thus, keeping the second inductor 214 partially energized. In other modes of operation, the current, Ib, does decay to zero amps during an OFF pulse.

In advance of another ON pulse, the power supply 216 is turned on to reapply the DC voltage, V₂₁₆ (Block 406). In this way, current, Ib, is injected into the second inductor 214 in advance of when the asymmetric periodic voltage is desired so that the asymmetric periodic voltage quickly rises. As shown in FIG. 6 for example, the power supply 216 is turned on at a time, t_{dc_on}, which is a time, t_{advance}, before the switching action (the closing and opening) of the switch 220 begins at a time, t_{switching_on}. It should be noted that the current, Ib, continues to be circulated within the bias supply after the DC voltage, V₂₁₆ is reapplied at tde on until the switch-mode action of the switch 220 is initiated again at the time t_{switching_on}. And as shown, the application of the voltage, V₂₁₆, at t_{dc_on} results in a substantial increase in the current, Ib, being injected in the second inductor 214; thus, enabling the periodic voltage waveform, V₂₁₀, to quickly reach its steady state parameter values.

It should be recognized that the switch 220 depicted herein generally represents one or more switches that are capable of closing and opening to connect and disconnect, respectively, a current pathway. For example, the switch 220 may be realized by a plurality of switches arranged is series (for enhanced voltage capability), may be realized by a plurality of switches arranged is parallel (for enhanced current capability), or the switch 220 may be comprised of a plurality of switches arranged in a series-parallel combination (for enhanced voltage and or current capability). In these variations, one of ordinary skill in the art will recognize that each switch that is used to realize the switch 220 may be synchronously driven by a corresponding drive signal.

In many implementations, the switch disclosed herein are realized by a field-effect switches such as metal-oxide semiconductor field-effect transistors (MOSFETS), and in some implementations, the switches are realized by silicon carbide metal-oxide semiconductor field-effect transistors (SiC MOSFETs) or gallium nitride metal-oxide semiconductor field-effect transistors (GaN MOSFETs). As another example, the switches may be realized by an insulated gate bipolar transistor (IGBT). In these implementations, the gate drive signal generator 636 may comprise an electrical driver known in the art that is configured to apply electrical drive signals to the switches responsive to signals from the timing parameter estimator 634 and/or the one or more compensators 632. It is also contemplated that the drive signals may be sent via optical lines to convey optical switching signals. And the switches may switch in response to the optical signal and/or optical signals that are converted to an electrical drive signal.

It should also be recognized that any of the diodes depicted herein may be realized by a plurality of diodes. For example, any diode may be realized by a plurality of series-connected diodes (to enhance voltage capability), may be realized by a plurality of diodes arranged in parallel (to enhance current capability), or may be comprised of a plurality of diodes arranged in a series-parallel combination (for enhanced voltage and or current capability).

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The various illustrative logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such the processor can read information from, and write information to, the storage medium. In the alternative, the storage medium may be integral to the processor. The processor and the storage medium may reside in an ASIC.

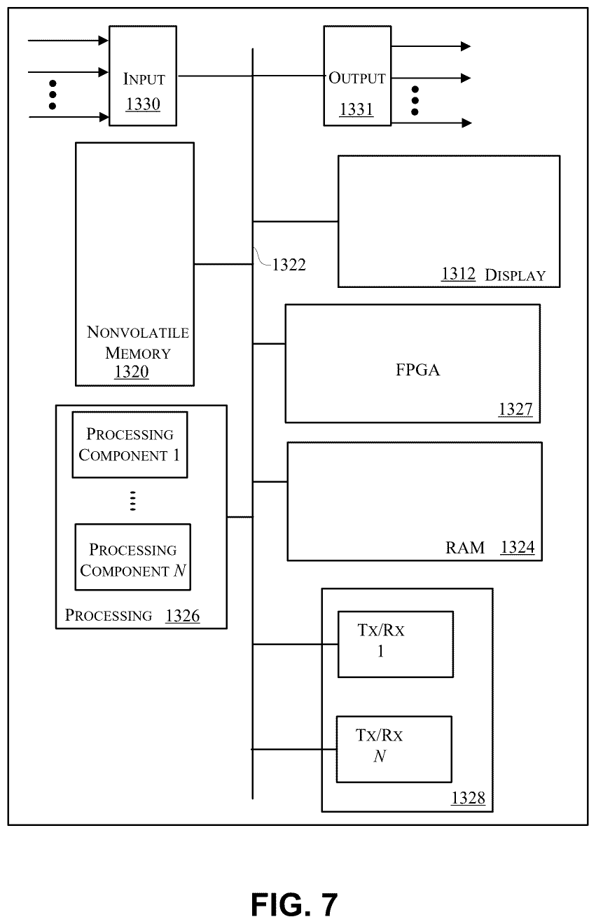

Many embodiments and methods described herein may be realized using a processor in connection with processor executable instructions and a field programmable gate array (programmed by hardware description language instructions). The nonvolatile memory may be encoded with instructions that are executable by a processor and/or are readable by a field programmable gate array, e.g., to program the field programmable gate array. In some embodiments, the FPGA is used for high-speed processing and control, including switching control, measurement, pulsing, and multi-level operation while a processor is utilized for other lower-speed processing. Referring to FIG. 7 for example, shown is a block diagram depicting physical components of a controller that may be utilized to realize control aspects disclosed herein.

As shown, in this embodiment a display 1312 and nonvolatile memory 1320 are coupled to a bus 1322 that is also coupled to random access memory (“RAM”) 1324, a processing portion (which includes N processing components) 1326, a field programmable gate array (FPGA) 1327, and a transceiver component 1328 that includes N transceivers. Although the components depicted in FIG. 7 represent physical components, FIG. 7 is not intended to be a detailed hardware diagram; thus, many of the components depicted in FIG. 7 may be realized by common constructs or distributed among additional physical components. Moreover, it is contemplated that other existing and yet-to-be developed physical components and architectures may be utilized to implement the functional components described with reference to FIG. 7.

This display 1312 generally operates to provide a user interface for a user, and in several implementations, the display is realized by a touchscreen display. In general, the nonvolatile memory 1320 is non-transitory memory that functions to store (e.g., persistently store) data and processor-executable code (including executable code that is associated with effectuating the methods described herein). In some embodiments for example, the nonvolatile memory 1320 includes bootloader code, operating system code, file system code, and non-transitory processor-executable code to facilitate the execution of methods for pulse-mode control of the bias supply 208 described herein. The nonvolatile memory 1320 may be encoded with instructions that are executable by a processor and/or are readable by a field programmable gate array, e.g., to program the field programmable gate array wherein the instructions (when executed by the processing portion 1326 or when effectuated by the FPGA 1327) cause the bias supply 208 to carry out the methods disclosed herein. Those of ordinary skill in the art will also appreciate that the FPGA 1327 may also comprise a non-transitory medium that is integrated with the FPGA.

In many implementations, the nonvolatile memory 1320 is realized by flash memory (e.g., NAND or ONENAND memory), but it is contemplated that other memory types may be utilized as well. Although it may be possible to execute the code from the nonvolatile memory 1320, the executable code in the nonvolatile memory is typically loaded into RAM 1324 and executed by one or more of the N processing components in the processing portion 1326.

The N processing components in connection with RAM 1324 generally operate to execute the instructions stored in nonvolatile memory 1320 to enable execution of the algorithms and functions disclosed herein. It should be recognized that several algorithms are disclosed herein, but some of these algorithms are not represented in flowcharts. Processor-executable code to effectuate methods described herein may be persistently stored in nonvolatile memory 1320 and executed by the N processing components in connection with RAM 1324. As one of ordinarily skill in the art will appreciate, the processing portion 1326 may include a video processor, digital signal processor (DSP), micro-controller, graphics processing unit (GPU), or other hardware processing components or combinations of hardware and software processing components (e.g., an FPGA or an FPGA including digital logic processing portions).

In addition, or in the alternative, non-transitory FPGA-configuration-instructions may be persistently stored in nonvolatile memory 1320 and accessed (e.g., during boot up) to configure a field programmable gate array (FPGA) to implement the algorithms disclosed herein.

The input component 1330 may receive power related signals (e.g., the signals 236, 238, and 240 indicative of Ib, output current, Iout, and voltage, V210) obtained (e.g., by current transducers, VI sensors, and/or voltage sensors. The input component 1330 may also receive the Sync_in signal. The output component 1331 may provide analog and/or digital signals to provide information or to provide control signals. As examples without limitation, the output component 1331 may provide the gate drive signal 240, the V_{210_control} signal, and the Sync_out signal.

Although not required, in some implementations the FPGA 1327 may sample the power-related signals and provide the digital representations of output current, Iout, and voltage V₂₁₀. In some embodiments, the processing components 1326 (in connection with processor-executable instructions stored in the nonvolatile memory 1320) are used to realize the data processing module, comparators, and compensators disclosed herein. But the FPGA 1327 may also be used to implement these functions. In addition, the input component 1330 may receive phase information and/or as discussed a synchronization signal between bias supplies 108 and source generator 112 that are indicative of one or more aspects of an environment within a plasma processing chamber 101 and/or synchronized control between a source generator and the single switch bias supply. The signals received at the input component 1330 may include, for example, synchronization signals, power control signals to the various generators and power supply units, or control signals from a user interface. Those of ordinary skill in the art will readily appreciate that any of a variety of types of sensors such as, without limitation, directional couplers and voltage-current (VI) sensors, may be used to sample power parameters, such as voltage and current, and that the signals indicative of the power parameters may be generated in the analog domain and converted to the digital domain.

The depicted transceiver component 1328 includes N transceiver chains, which may be used for communicating with external devices via wireless or wireline networks. Each of the N transceiver chains may represent a transceiver associated with a particular communication scheme (e.g., WiFi, Ethernet, Profibus, etc.).

As will be appreciated by one skilled in the art, aspects of the present disclosure may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present disclosure may take the form of a computer program product embodied in one or more computer readable medium(s) having computer readable program code embodied thereon.

As used herein, the recitation of “at least one of A, B and C” or “at least one of A, B or C” is intended to mean “either A, B, C or any combination of A, B and C.” The previous description of the disclosed embodiments is provided to enable any person skilled in the art to make or use the present disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

What is claimed is:

1. An apparatus to produce a waveform, the apparatus comprising:
at least one switch in a current path that couples a first node to a second node;
a power supply coupled to the current path; and
a controller configured to:
while the power supply is applying power, repeatedly close and open the at least one switch to produce peak voltages and portions between the peak voltages; and
while the power supply is not applying power, close the at least one switch to circulate current through the at least one switch and the power supply.

2. The apparatus of claim 1, wherein the controller is configured to control the power supply to apply power in advance of an ON pulse.

3. The apparatus of claim 2, wherein the controller is configured to receive a signal that indicates when the ON pulse begins.

4. The apparatus of claim 1, wherein the second node is coupled to the first node via a first inductor to form the current path.

5. The apparatus of claim 1, wherein the power supply is arranged in series with a second inductor, and the series arrangement of the power supply and the second inductor is coupled between the current path and the second node.

6. The apparatus of claim 5, wherein the current is circulated through the at least one switch, the second inductor, and the power supply.

7. The apparatus of claim 1, wherein the power supply is controllable to control current provided to the first node to control a ramped voltage between each of the peak voltages at the first node.

8. A method for producing a waveform comprising:
applying, during an ON pulse, a waveform using switching of at least one switch in connection with a DC voltage;
removing the DC voltage and closing the at least one switch to circulate current during an OFF pulse;
reapplying, in advance of another ON pulse, the DC voltage; and
initiating the switching after reapplying the DC voltage to reapply the waveform during another ON pulse.

9. The method of claim 8, wherein applying the waveform comprises repeatedly coupling a voltage to, and decoupling the voltage from, a first node to produce peaks of the waveform.

10. The method of claim 9, wherein applying the waveform comprises repeatedly coupling the first node to, and decoupling the first node from, a second node via a switch and a first inductor to produce the peaks of the waveform.

11. The method of claim 10 comprising:
providing the DC voltage to a second inductor to produce current to create a negative voltage ramp between each of the peaks of the waveform.

12. The method of claim 8, wherein each cycle of the waveform comprises a peak voltage, a voltage step following the peak voltage, and a ramped voltage following the voltage step.

13. The method of claim 8, wherein the DC voltage is a greater magnitude than-1000 volts.

14. A system, the system comprising:
a source generator configured to apply pulsed power to a plasma chamber; and
a bias supply configured to:
apply, during an ON pulse of the source generator, a waveform using switching in connection with a DC voltage;
removing the DC voltage while circulating current during an OFF pulse of the source generator;
reapply, in advance of another ON pulse, the DC voltage; and
initiating the switching after reapplying the DC voltage to reapply the waveform during the other ON pulse.

15. The system of claim 14, wherein the bias supply is configured to apply the waveform by repeatedly coupling a voltage to, and decoupling the voltage from, a first node to produce peaks of the waveform.

16. The system of claim 15, wherein the bias supply is configured to apply the waveform by repeatedly coupling the first node to, and decoupling the first node from, a second node via a switch and a first inductor to produce the peaks of the waveform.

17. The system of claim 16 wherein the bias supply is configured to provide the DC voltage to a second inductor to produce current to create a negative voltage ramp between each of the peaks of the waveform.

18. The system of claim 14, wherein each cycle of the waveform comprises a peak voltage, a voltage step following the peak voltage, and a ramped voltage following the voltage step.

19. The system of claim 14, wherein the DC voltage is a greater magnitude than-1000 volts.
